(19) United States
(12) Patent Application Publication
(10) Pub. No.: US 2025/0226241 A1
(43) Pub. Date: Jul. 10, 2025

(54) SEMICONDUCTOR WAFER GRINDING WHEEL AND SEMICONDUCTOR WAFER POLISHING APPARATUS INCLUDING THE SAME

(71) Applicant: SAMSUNG ELECTRONICS CO., LTD., SUWON-SI (KR)

(72) Inventors: Yeon Su SONG, Suwon-si (KR); Jwa Hyeon KIM, Suwon-si (KR)

(21) Appl. No.: 18/822,523

(22) Filed: Sep. 3, 2024

(30) Foreign Application Priority Data
Jan. 8, 2024 (KR) 10-2024-0002873

(51) Int. Cl. H01L 21/67; B24B 7/22

(52) U.S. Cl. CPC H01L 21/67092; B24B 7/228

(57) ABSTRACT

A semiconductor wafer polishing apparatus includes: a grinding wheel including a plurality of grinding tip units, wherein the grinding tip units are stacked in a recessed inner area of the grinding wheel; and a chuck table disposed below the grinding wheel and having a semiconductor wafer that is loaded on its top surface, wherein the grinding wheel sequentially uses the plurality of grinding tip units, starting from a lowermost grinding tip unit disposed adjacent to a bottom surface of the grinding wheel.

### CROSS-REFERENCE TO RELATED APPLICATION

This application claims priority under 35 USC § 119 to Korean Patent Application No. 10-2024-0002873 filed on Jan. 8, 2024 in the Korean Intellectual Property Office, the disclosure of which is incorporated by reference herein in its entirety.

### TECHNICAL FIELD

The present inventive concept relates to a semiconductor wafer polishing apparatus and, more particularly, to a semiconductor wafer grinding wheel and semiconductor wafer polishing apparatus including the same.

### DISCUSSION OF THE RELATED ART

Generally, a semiconductor packaging process includes a pre-process that forms a layout pattern on the front side of a wafer and a post-process that grinds the back side of the wafer. The back grinding process refers to the process of polishing the back side of the wafer after the pre-process to achieve a desired thickness for the wafer. By grinding the wafer to the desired thickness through back grinding process, it is possible not only to reduce the thickness of a chip and thereby increase the integration density of the chip but also to increase the thermal conductivity of the chip and dissipate heat generated during operation.

For a back grinding process, a grinding wheel may be used. As the grinding process progresses, grinding tips may wear out, which may result in a regular replacement of the grinding wheel at certain intervals.

However, if the time for the detachment and attachment of the grinding wheel in a semiconductor wafer polishing apparatus is prolonged, it may affect the speed of semiconductor production by interrupting the packaging (or grinding) process during replacement. In addition, with a recent trend toward smart factories, semiconductor fabrication facilities (or fabs) are moving toward process automation, which may create a desire for the development of automatic replacement technology for consumables such as grinding wheels.

### SUMMARY

According to an embodiment of the present inventive concept, a semiconductor wafer polishing apparatus includes: a grinding wheel including a plurality of grinding tip units, wherein the grinding tip units are stacked in a recessed inner area of the grinding wheel; and a chuck table disposed below the grinding wheel and having a semiconductor wafer that is loaded on its top surface, wherein the grinding wheel sequentially uses the plurality of grinding tip units, starting from a lowermost grinding tip unit disposed adjacent to a bottom surface of the grinding wheel.

According to an embodiment of the present inventive concept, a grinding wheel mounted in a semiconductor wafer polishing apparatus includes: an annular-shaped first grinding tip unit including a plurality of first opening grooves and a plurality of grinding tips, which protrude from a bottom surface of the first grinding tip unit; and an annular-shaped second grinding tip unit including a plurality of second opening grooves at positions corresponding to the first opening grooves and a plurality of grinding tips, which protrude from a bottom surface of the second grinding tip unit, wherein the first and second grinding tip units are stacked in a lower recess of the grinding wheel.

According to an embodiment of the present inventive concept, a semiconductor wafer polishing apparatus includes: a grinding wheel including a plurality of grinding tip units disposed in a lower recess of the grinding wheel; and a chuck table disposed below the grinding wheel and having a semiconductor wafer loaded on its top surface, wherein each of the plurality of grinding tip units includes first threads on its outer circumferential surface and a plurality of grinding tips disposed on its bottom surface, which polish the semiconductor wafer.

### BRIEF DESCRIPTION OF THE DRAWINGS

The above and other aspects and features of the present inventive concept will become more apparent by describing in detail exemplary embodiments thereof with reference to the attached drawings, in which:

FIG. 1 is a diagram illustrating a semiconductor wafer polishing apparatus according to embodiments of the present inventive concept.

FIG. 2 is a perspective view illustrating the grinding wheel.

FIGS. 3 and 4 are partial enlarged perspective views illustrating area A of the grinding wheel of FIG. 2.

FIGS. 5 and 6 are partial perspective views illustrating the wheel shank of the grinding wheel.

FIGS. 7, 8A, and 8B are partial enlarged perspective views of area C of FIG. 5 illustrating a fixing pin according to embodiments of the present inventive concept.

FIG. 9 is a perspective view of replacement equipment capable of automating the replacement of a grinding wheel according to embodiments of the present inventive concept.

FIGS. 10 and 11 are perspective views illustrating the operational states of the replacement equipment of FIG. 9.

FIG. 12 is a perspective view of a grinding wheel separated from a semiconductor wafer polishing apparatus.

### DETAILED DESCRIPTION OF THE EMBODIMENTS

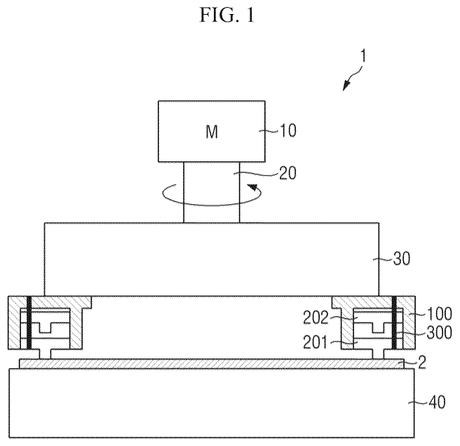

A grinding wheel, a semiconductor wafer polishing apparatus including the grinding wheel, and replacement equipment for the grinding wheel according to embodiments of the present inventive concept will hereinafter be described with reference to FIGS. 1 through 12.

FIG. 1 is a diagram illustrating a semiconductor wafer polishing apparatus according to some embodiments of the present disclosure.

Referring to FIG. 1, a semiconductor wafer polishing apparatus 1 may include a chuck table 40, on which a semiconductor wafer 2 is placed, a grinding wheel 100 on the chuck table 40, a fixing body 30, which fixes the grinding wheel 100, a motor 10, which rotates the grinding wheel 100, and a connecting part 20, which connects the fixing body 30 and the motor 10 to each other. The motor 10, the connecting part 20, the fixing body 30, the grinding wheel 100, and the chuck table 40 may be disposed to be sequentially stacked on each other in a vertical direction.

The semiconductor wafer 2 may be disposed on the chuck table 40. For example, the semiconductor wafer 2 may be disposed on the chuck table 40 such that a back side of the semiconductor wafer 2 faces the grinding wheel 100. The back side of the semiconductor wafer 2 is opposite to a front side of the semiconductor wafer 2, on which devices may be formed, and the front side may face the chuck table 40. For example, the chuck table 40 may load the semiconductor wafer 2 with its back side facing upward. The chuck table 40 may rotate at a constant speed in one direction.

The grinding wheel 100 may be disposed to face the back side of the semiconductor wafer 2. The grinding wheel 100 may be physically connected to the motor 10 through the connecting part 20 and the fixing body 30 and may thereby be able to rotate at a constant speed in one direction according to the rotational motion of the motor 10. The rotational direction of the grinding wheel 100 and the rotational direction of the chuck table 40 may be opposite to each other. In addition, the grinding wheel 100 and the chuck table 40 may rotate in the same direction as each other but at different speeds from each other.

The fixing body 30 may move in a horizontal direction (for example, an X- or Y-axis direction) to adjust the position of the grinding wheel 100 on the semiconductor wafer 2. In embodiments of the present inventive concept, the grinding wheel 100 may be disposed at the center of the semiconductor wafer 2 or may be disposed to cover part of the semiconductor wafer 20.

The grinding wheel 100 may include a wheel shank, a plurality of grinding tip units 201 and 202, which are stacked and embedded in the wheel shank, and fixing pins 300. The wheel shank may be implemented with an annular shape having a bottom surface that is recessed inwardly. The grinding tip units 201 and 202 may be disposed on a recessed inner side or in a lower recess of the wheel shank to be stacked on each other. Each of the grinding tip units 201 and 202 may have an annular shape and may include a plurality of tips on its bottom surface. The tips may be arranged in a protruding manner on the bottom surface of each of the grinding tip units 201 and 202. The tips may roughly polish the surface of the semiconductor wafer 2 to reduce the thickness of the semiconductor wafer 2 when the grinding wheel 100 rotates. The tips may be formed of a material such as, for example, diamond.

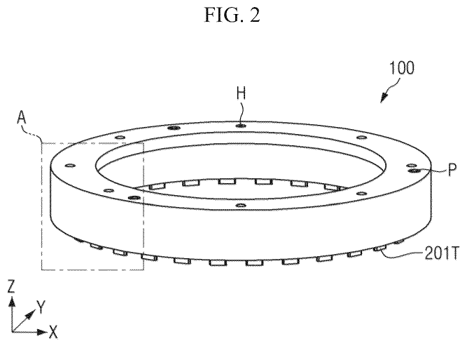

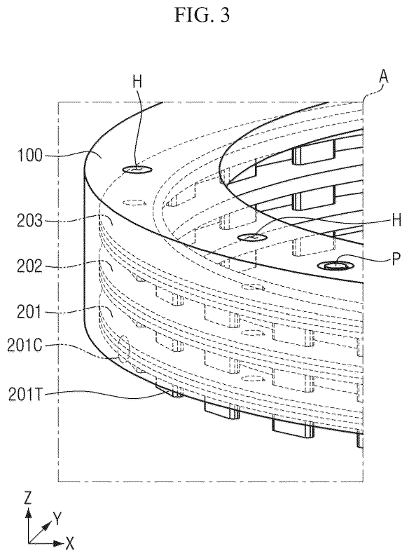

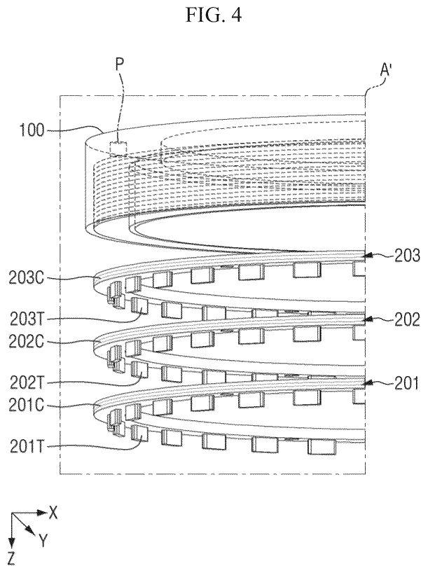

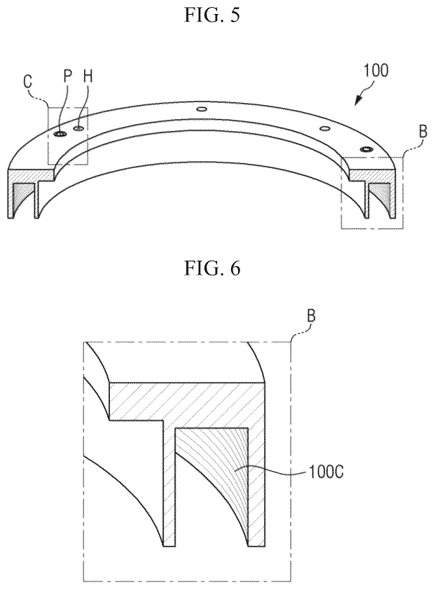

FIG. 2 is a perspective view illustrating the grinding wheel 100. FIGS. 3 and 4 are partial enlarged perspective views illustrating area A of the grinding wheel 100 of FIG. 2, and FIGS. 5 and 6 are partial perspective views illustrating the wheel shank of the grinding wheel 100.

Referring to FIGS. 2 to 6, the wheel shank of the grinding wheel 100 may be implemented in an annular shape similar to the grinding tip units 201 and 202.

The top surface of the wheel shank may have a flat plane in the horizontal direction, and the bottom surface of the wheel shank may have a lower recess that is inwardly recessed. The wheel shank may house a plurality of grinding tip units 201, 202, and 203, which stacked on top of one another in the lower recess of the wheel shank of the grinding wheel 100. For example, the wheel shank may house three grinding tip units. The grinding tip units 201, 202, and 203 may be sequentially used, starting from the grinding tip unit 201, which is disposed at the bottom of the wheel shank of the grinding wheel 100. In the example of FIGS. 2 through 6, the grinding tip unit 201 that is disposed at the bottom of the wheel shank of the grinding wheel 100 may be used first, and when the grinding tip unit 201 wears out, the grinding tip unit 202 may be used to move and fix the grinding tip unit 202 to the bottom surface of the wheel shank of the grinding wheel 100 after detaching the grinding tip unit 201 from the grinding wheel 100.

As illustrated in FIGS. 3 and 4, each of the grinding tip units 201, 202, and 203 may include first threads 201C, 202C, or 203C on its outer circumferential surface. As illustrated in FIGS. 5 and 6, the wheel shank of the grinding wheel 100 may include second threads 100C on the inner surface of its lower recess. The first threads 201c, 202C, or 203C are inserted into the lower recess of the grinding wheel 100 by engaging with and rotating along the second threads 100C on the inner circumferential surface of the lower recess of the grinding wheel 100. The grinding tip unit 203 may be mounted in the grinding wheel 100 by rotating the grinding tip unit 203 in a bottom-to-top direction. The grinding tip unit 202 may be mounted below the grinding tip unit 203 by rotating the grinding tip unit 202 in the same manner as the grinding tip unit 203, and the grinding tip unit 201 may be mounted below the grinding tip unit 202 by rotating the grinding tip 201 in the same manner as the grinding tip unit 202.

Each of the grinding tip units 201, 202, and 203 includes a plurality of grinding tips 201T, 202T, or 203T on its bottom surface. For example, the grinding tips 201T, 202T, or 203T may also be referred to as blades, abrasive structures, or grinding teeth. While rotating by the motor 10 with grinding tips (201T, 202T, and 203T) in contact with the semiconductor wafer 2, the grinding wheel 100 polishes the surface of the semiconductor wafer 2, thereby flattening the surface of the semiconductor wafer 2 and forming the semiconductor wafer 2 to a predetermined thickness.

In the example of FIGS. 2 through 6, the grinding wheel 100 may include a plurality of first opening grooves H for receiving the fixing pins 300. For example, the wheel shank of the grinding wheel 100 may include a plurality of first opening grooves H for receiving the fixing pins 300. Each of the grinding tip units 201, 202, and 203 may also include a plurality of first opening grooves H, which are of the same diameter as the first opening grooves H of the grinding wheel 100, at positions corresponding to the first opening grooves H of the grinding wheel 100.

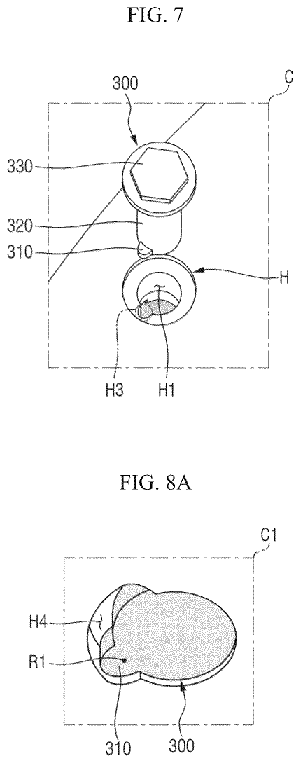

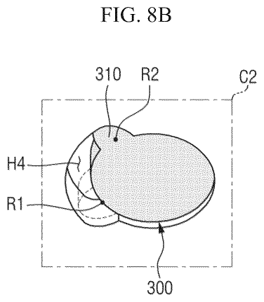

The grinding tip units 201, 202, and 203 may be fixed by the fixing pins 300 to prevent detachment from the grinding wheel 100 regardless of the rotational movement of the fixing body 30 by the motor 10. The fixing pins 300 may be disposed to pass through the grinding wheel 100 and each of the grinding tip units 201, 202, and 203, and may have a locking structure to ensure that the grinding tip units 201, 202, and 203 remain stationary and fixed to the grinding wheel 100. The fixing pins 300 will be described later in further detail with reference to FIGS. 7 and 8.

In the example of FIGS. 2 through 6, the grinding wheel 100 may be disposed on the bottom surface of the fixing body 30 and may include second opening grooves P for body fixing screws that fix the grinding wheel 100 to the fixing body 30. For example, the body fixing screws are coupled into the second opening grooves P to fix the grinding wheel 100 to the fixing body 30 of the semiconductor wafer polishing apparatus 1. The first opening grooves H and the second opening grooves P are disposed at different locations from one another on the top surface of the grinding wheel 100.

FIGS. 7, 8A, and 8B are partial enlarged perspective views of area C of FIG. 5 illustrating a fixing pin according to embodiments of the present inventive concept.

Referring to FIG. 7, a fixing pin 300 may include a locking protrusion member 310, a pillar member 320, and a head member 330. The pillar member 320 of the fixing pin 300 passes through a first opening groove H of the grinding wheel 100, and the head member 330, which has a diameter larger than that of the first opening groove H, is disposed on the top surface of the grinding wheel 100 such that it does not pass through the first opening groove H, even if the pillar member 320 penetrates the grinding wheel 100 and the grinding tip units 201, 202, and 203. Thus, the head member 330 may prevent the grinding tip units 201, 202, and 203 and the fixing pin 300 from falling out of the grinding wheel 100.

The head member 330 may be a thin plate-like polyhedron, such as a hexahedron or

an octahedron. If formed as a polyhedron, the head member 330 may facilitate the tightening or loosening of the fixing pin 300 into the grinding wheel 100 with a tool. In addition, the head member 330 may be formed as another shape such as a cylindrical shape.

The first opening groove H may be formed to include a cylindrical main circumferential area H1 and a sub-area (H3 and H4), which extend from the main circumferential area H1. The main circumference area H1 has an opening diameter corresponding to the diameter of the pillar member 320 of the fixing pin 300, and the sub-area (H3 and H4) may have a pillar shape corresponding to the shape of the locking protrusion member 310 of the fixing pin 300. For example, the main circumference area Hl may have a pillar shape or cylindrical shape corresponding to that of the pillar member 320. As another example, the first sub-area H3 may be exposed by the grinding wheel 100 from a plan view, and the second sub-area H4 may be covered by the grinding wheel 100 from a plan view. For example, the second sub-area H4 may laterally extend into the grinding wheel 100 from the main circumference area H1. The main circumference area H1 may have an opening diameter that is larger than that of the sub-area (H3 and H4). A first opening groove H of each of the grinding tip units 201, 202, and 203 may also include a cylindrical main circumferential area H1, a first sub-area H3, and a second sub-area H4, which is a wider recess area in a certain rotation direction from the first sub-area H3. For example, in each of the grinding tip units 201, 202 and 203, the second sub-area H4 may extend from the main circumference area H1 into each of the grinding tip units 201, 202 and 203.

The locking protrusion member 310 may be rotated at the bottom surfaces of the grinding tip units 201, 202, and 203 to lock at least one of the grinding tip units 201, 202, and 203 in place on the grinding wheel 100. For example, referring to FIG. 8A, when the pillar member 320 and the locking protrusion member 310 pass through the first opening groove H of the grinding wheel 100 and at least one of the grinding tip units 201, 202, and 203, the reference point of the locking protrusion member 310 may be positioned at R1 in the first sub-area H3. Then, referring to FIG. 8B, as the locking protrusion member 310 is rotated from the reference point (R1) of the locking protrusion member 310 to a moving point R2 using the head member 330, the locking protrusion member 310 becomes caught and secured by the edge of the second sub-area H4. For example, at the moving point R2, the locking protrusion member 310 may be in contact with an upper surface that defines the second sub-area H4, and the upper surface defining the second sub-area H4 may correspond to a lower surface of the grinding wheel 100 or the grinding tip units 201, 202, or 203.

A stable grinding wheel 100 during operation can be implemented by using the fixing pins 300 and the first opening grooves H of the grinding wheel 100 and the grinding tip units 201, 202, and 203, as illustrated in FIGS. 7 and 8.

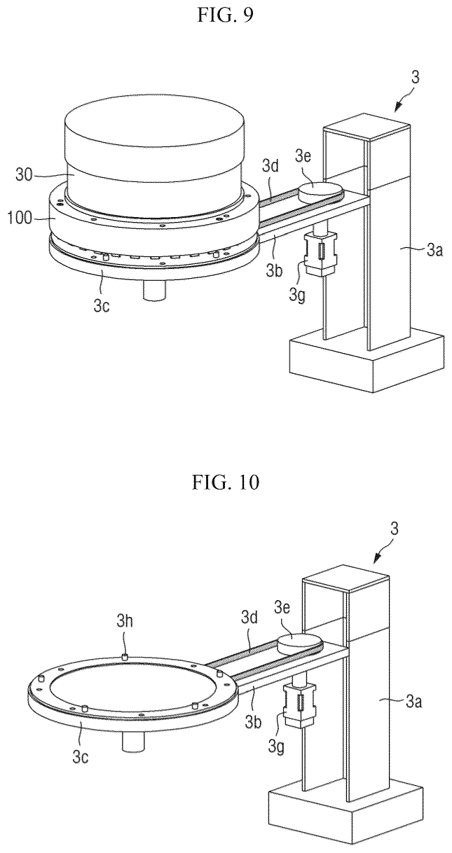

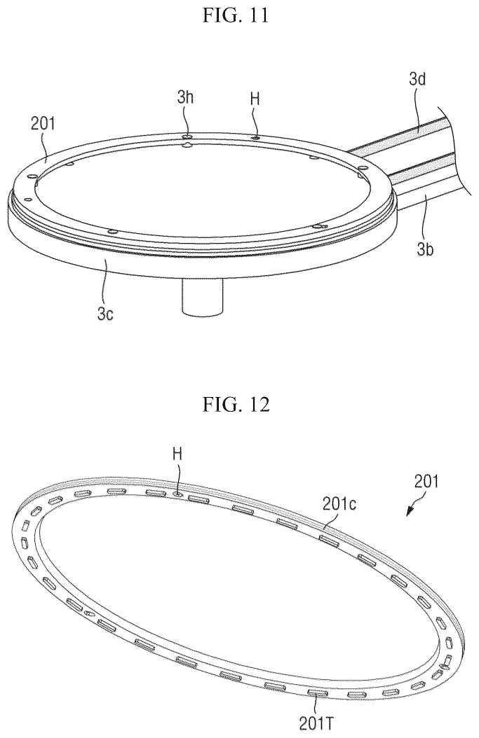

FIG. 9 is a perspective view of replacement equipment capable of automating the replacement of a grinding wheel according to embodiments of the present inventive concept, and FIGS. 10 and 11 are perspective views illustrating the operational states of the replacement equipment of FIG. 9. FIG. 12 is a perspective view of a grinding wheel separated from a semiconductor wafer polishing apparatus.

Referring to FIGS. 9 through 12, a grinding wheel 100 may be manually replaced by a user. However, in embodiments of the present inventive concept, the grinding wheel 100 may also be replaced by using replacement equipment 3.

The replacement equipment 3 may include a transfer body 3a, a transfer arm 3b, a drive rotation motor 3g, a drive wheel 3e, a drive band 3d, and a table unit 3c with a replacement grinding wheel 100 attachable to or detachable from the upper surface of the table unit 3c.

As the drive wheel 3e is rotated by the drive rotation motor 3g, the table unit 3c may rotate according to the movement of the drive band 3d, which is connected to the drive wheel 3e, and as a result, the transfer arm 3b may attach a grinding tip unit 201 to or detach the grinding tip unit 201 from the semiconductor wafer polishing apparatus 1.

The table unit 3c includes a key 3h, which protrudes at a position corresponding to a first opening groove H at its top surface that faces the grinding wheel 100. The key 3h may lock or unlock a fixing pin 300 of the grinding wheel 100, allowing the grinding tip unit 200 to be mounted in or detached from the semiconductor wafer polishing apparatus 1.

The replacement equipment 3 detaches the fixing pin 300 to separate a lowermost grinding tip unit 201 among one or more grinding tip units embedded in the grinding wheel 100. Then, the replacement equipment 3 rotates an upper grinding tip unit, embedded within the lower recess of the grinding wheel 100, along the first threads (201C, 202C, and 203C) and the second threads 100C, moves the upper grinding tip unit to the bottom surface of the grinding wheel 100, and locks the fixing pin 300 to allow the grinding wheel 100 to operate with the newly moved grinding tip unit.

For example, as illustrated in FIGS. 11 and 12, the replacement equipment 3 may separate the grinding tip unit 201 from the semiconductor wafer polishing apparatus 1. In the example of FIGS. 11 and 12, first opening grooves H of the grinding tip unit 201 are adjusted or moved to correspond to the position of the key 3h of FIG. 11, allowing the grinding tip unit 201 to be separated from the semiconductor wafer polishing apparatus 1 and placed on the table unit 3c.

While the present inventive concept has been described with reference to embodiments thereof, it will be understood by those of ordinary skill in the art that various changes in form and details may be made thereto without departing from the spirit and scope of the present inventive concept.

What is claimed is:

1. A semiconductor wafer polishing apparatus comprising:
a grinding wheel including a plurality of grinding tip units, wherein the grinding tip units are stacked in a recessed inner area of the grinding wheel; and
a chuck table disposed below the grinding wheel and having a semiconductor wafer that is loaded on its top surface,
wherein the grinding wheel sequentially uses the plurality of grinding tip units, starting from a lowermost grinding tip unit disposed adjacent to a bottom surface of the grinding wheel.

2. The semiconductor wafer polishing apparatus of claim 1, wherein each of the plurality of grinding tip units includes first threads, which are formed on an outer circumferential surface of a corresponding grinding tip unit.

3. The semiconductor wafer polishing apparatus of claim 2, wherein
the grinding wheel includes second threads, which are formed on an inner circumferential surface of a recessed inner area of the grinding wheel, and
the first threads of each of the plurality of grinding tip units are inserted into a lower recess of the grinding wheel by engaging with and rotating along the second threads.

4. The semiconductor wafer polishing apparatus of claim 1, wherein a top surface of the grinding wheel and each of the plurality of grinding tip units includes a plurality of first opening grooves at corresponding positions.

5. The semiconductor wafer polishing apparatus of claim 4, wherein the plurality of grinding tip units are fixed to the grinding wheel via fixing pins, which are disposed in the first opening grooves.

6. The semiconductor wafer polishing apparatus of claim 1, wherein
the grinding wheel further includes second opening grooves, into which body fixing screws for fixing the grinding wheel to a fixing body of the semiconductor wafer polishing apparatus, and
the first opening grooves and the second opening grooves are disposed at different locations from one another on a top surface of the grinding wheel.

7. A grinding wheel mounted in a semiconductor wafer polishing apparatus, comprising:
an annular-shaped first grinding tip unit including a plurality of first opening grooves and a plurality of grinding tips, which protrude from a bottom surface of the first grinding tip unit; and
an annular-shaped second grinding tip unit including a plurality of second opening grooves at positions corresponding to the first opening grooves and a plurality of grinding tips, which protrude from a bottom surface of the second grinding tip unit,
wherein the first and second grinding tip units are stacked in a lower recess of the grinding wheel.

8. The grinding wheel of claim 7, wherein each of the first and second grinding tip units includes first threads, which are formed on an outer circumferential surface of a corresponding grinding tip unit.

9. The grinding wheel of claim 8, further comprising second threads, which are formed on an inner circumferential surface of the lower recess and engage with the first threads.

10. The grinding wheel of claim 7, further comprising a plurality of third opening grooves, which are disposed on a top surface of the grinding wheel at positions corresponding to the first opening grooves and the second opening grooves, and
the grinding wheel includes a plurality of fixing pins, which penetrate the first opening grooves, the second opening grooves, and the third opening grooves.

11. The grinding wheel of claim 10, wherein each of the fixing pins includes
a head member, which has a diameter larger than that of the first opening grooves and the second opening grooves,
a pillar member, which is disposed in first, second, and third opening grooves, and
a locking protrusion member, which rotates on a bottom surface of the first grinding tip unit and thereby locks the first and second grinding tip units to be fixed to the grinding wheel.

12. The grinding wheel of claim 11, wherein each of the first opening grooves and second opening grooves includes:
a main circumferential area, which has an opening diameter corresponding to a diameter of the pillar member of a corresponding fixing pin;
a first sub-area, which has a shape corresponding to the locking protrusion member of the corresponding fixing pin and is opened toward an opening direction of the main circumferential area to be penetrated by the locking protrusion member of the corresponding fixing pin; and
a second sub-area, which has a shape corresponding to the locking protrusion member of the corresponding fixing pin and is not opened toward the opening direction of the main circumferential area.

13. The grinding wheel of claim 10, wherein
the first grinding tip unit is separated from the grinding wheel by detaching the fixing pins via replacement equipment, and
the second grinding tip unit, mounted in the lower recess, is moved to and placed on a bottom surface of the grinding wheel via the replacement equipment.

14. A semiconductor wafer polishing apparatus comprising:
a grinding wheel including a plurality of grinding tip units disposed in a lower recess of the grinding wheel; and
a chuck table disposed below the grinding wheel and having a semiconductor wafer loaded on its top surface,
wherein each of the plurality of grinding tip units includes first threads on its outer circumferential surface and a plurality of grinding tips disposed on its bottom surface, which polish the semiconductor wafer.

15. The semiconductor wafer polishing apparatus of claim 14, wherein the lower recess of the grinding wheel is shaped to be recessed upwardly from a bottom surface of the grinding wheel and includes second threads, which correspond to the first threads of each of the plurality of grinding tip units, on its inner circumferential surface.

16. The semiconductor wafer polishing apparatus of claim 14, wherein
a plurality of first opening grooves are disposed in the grinding wheel and each of the plurality of grinding tip units at corresponding positions, and
a plurality of fixing pins penetrate the first opening grooves.

17. The semiconductor wafer polishing apparatus of claim 16, wherein the grinding wheel, via replacement equipment, unlocks the fixing pins, separates a lowermost grinding tip unit among the plurality of grinding tip units mounted in the grinding wheel, rotates and moves an upper grinding tip unit mounted above the lowermost grinding tip unit, in the grinding wheel, to a bottom surface of the grinding wheel, and locks the fixing pins once the upper grinding tip unit is moved to the bottom surface of the grinding wheel.

18. The semiconductor wafer polishing apparatus of claim 16, wherein
the grinding wheel further includes second opening grooves disposed on its top surface, which are for fixing the grinding wheel to a fixing body that is connected to a motor, and
the first opening grooves and the second opening grooves are disposed at different locations from one another on the top surface of the grinding wheel.

19. The semiconductor wafer polishing apparatus of claim 16, wherein each of the fixing pins includes
a head member, which has a diameter larger than that of the first opening grooves,
a pillar member, which penetrates a corresponding first opening groove, and
a locking protrusion member, which rotates on a bottom surface of a lowermost grinding tip unit among the plurality of grinding tip units and thereby locks the plurality of grinding tip units to be fixed to the grinding wheel.

20. The semiconductor wafer polishing apparatus of claim 19, wherein each of the first opening grooves includes
a main circumferential area, which has an opening diameter corresponding to a diameter of the pillar member of a corresponding fixing pin,
a first sub-area, which has a shape corresponding to the locking protrusion member of the corresponding fixing pin and is opened toward an opening direction of the main circumferential area to be penetrated by the locking protrusion member of the corresponding fixing pin, and
a second sub-area, which has a shape corresponding to the locking protrusion member of the corresponding fixing pin and is not opened toward the opening direction of the main circumferential area.
